(19) United States
(12) Patent Application Publication
(10) Pub. No.: US 2024/0130188 A1
(43) Pub. Date: Apr. 18, 2024

(54) DISPLAY DEVICE AND METHOD OF MANUFACTURING THE SAME

(71) Applicant: Samsung Display Co., LTD., Yongin-si (KR)

(72) Inventors: HYUNEOK SHIN, Yongin-si (KR); DONGMIN LEE, Yongin-si (KR); JOONYONG PARK, Yongin-si (KR)

(21) Appl. No.: 18/199,643

(22) Filed: May 19, 2023

(30) Foreign Application Priority Data
Oct. 18, 2022 (KR) 10-2022-0133840

(51) Int. Cl. H10K 59/131; H10K 59/12; H10K 71/00

(52) U.S. Cl. CPC H10K 59/1315; H10K 59/1201; H10K 71/00

(57) ABSTRACT

A display device includes a substrate, a gate line on the substrate, an inorganic film on the substrate and covering the gate line and a sloped film on the inorganic film and covering a side surface of the inorganic film overlapping the gate line in a width direction of the gate line.

This application claims priority to Korean Patent Application No. 10-2022-0133840, filed on Oct. 18, 2022, and all the benefits accruing therefrom under 35 U.S.C. § 119, the content of which in its entirety is herein incorporated by reference.

### BACKGROUND

### 1. Field

Embodiments relate to a display device. More particularly, embodiments relate to the display device and a method of manufacturing the display device.

### 2. Description of the Related Art

The display device is a device that displays an image for providing visual information to a user. Among display devices, an organic light emitting diode display has recently attracted attention.

The organic light-emitting display device has a self-emission characteristic and does not use a separate light source, unlike a liquid crystal display device, such that the organic light-emitting display device typically has a reduced thickness and weight. In addition, the organic light emitting diode display may exhibit high quality characteristics such as low power consumption, high luminance, and high reaction speed.

Lines included in the display device may be formed in a fine structure to improve display quality. As widths of the lines decreases, cross-sectional areas of the lines decreases, such that resistance thereof may increase. When the cross-sectional areas of lines are widened to reduce resistance, a step structure may be formed thereon such that a subsequent process may be affected thereby.

### SUMMARY

In a display device, where a cross-sectional areas of lines therein are widened to reduce resistance, a stringer defect in which a residual film remains after etching to form the lines may occur. The residual film may react with a metal or the like in the subsequent process to cause a short circuit.

Embodiments provide a display device capable of implementing a low-resistance line.

Embodiments provide a method of manufacturing the display device.

A display device according to an embodiment includes a substrate, a gate line on the substrate, an inorganic film on the substrate and covering the gate line and a sloped film on the inorganic film and covering a side surface of the inorganic film overlapping the gate line in a width direction of the gate line.

In an embodiment, the sloped film may have a tapered shape.

In an embodiment, an angle between a side surface of the sloped film and the substrate may be less than an angle between a side surface of the gate line and the substrate.

In an embodiment, the gate line, the inorganic film, and the sloped film may overlap each other in the width direction of the gate line.

In an embodiment, a thickness of the sloped film may decrease as being away from the gate line in the width direction of the gate line.

In an embodiment, the sloped film may include an organic material and an inorganic material.

In an embodiment, the sloped film may include SiO₂.

In an embodiment, the sloped film may further include siloxane or polyimide.

In an embodiment, an angle between the side surface of the gate line and the substrate may be in a range of about 80 degrees to about 90 degrees.

In an embodiment, the display device may further include a data line on the sloped film.

In an embodiment, the data line may cross the gate line.

In an embodiment, the gate line may include copper.

In an embodiment, the gate line may include a metal layer including copper, a first alloy layer on the metal layer and a second alloy layer below the metal layer.

In an embodiment, each of the first alloy layer and the second alloy layer may include titanium.

In an embodiment, each of the first alloy layer and the second alloy layer may further include zinc, and a content of zinc included in each of the first alloy layer and the second alloy layer may in a range of about 40 atomic percent (at %) to about 70 at %.

In an embodiment, the sloped film further may overlap an upper surface of the gate line.

A display device according to an embodiment may include a substrate, a metal pattern on the substrate, a first inorganic film on the substrate and covering the metal pattern, a first sloped film on the first inorganic film and covering a side surface of the first inorganic film overlapping the metal pattern in a width direction of the metal pattern, and a gate line on the first sloped film and the first inorganic film.

In an embodiment, the display device may further include a second inorganic film line on the first sloped film and the first inorganic film and covering the gate line, and a second sloped film on the second inorganic film and covering a side surface of the second inorganic film overlapping the gate line in a width direction of the gate line.

In an embodiment, each of the first sloped film and the second sloped film may have a tapered shape.

In an embodiment, an angle between a side surface of the first sloped film and the substrate may be less than an angle between the side surface of the metal pattern and the substrate, and an angle between a side surface of the second sloped film and the substrate may be less than an angle between a side surface of the gate line and the substrate.

In an embodiment, each of the first sloped film and the second sloped film may include an organic material and an inorganic material.

A method of manufacturing a display device according to an embodiment may include forming a gate line on a substrate, forming an inorganic film on the substrate to cover the gate line and forming a sloped film on the inorganic film to cover a side surface of the inorganic film.

In an embodiment, the forming the sloped film may include applying a preliminary sloped layer on the inorganic film, and baking the preliminary sloped layer.

In an embodiment, the preliminary sloped layer may include an organic material and an inorganic material.

In an embodiment, the forming the gate line may include forming a first preliminary alloy layer on the substrate, forming a preliminary metal layer on the first preliminary alloy layer, forming a second preliminary alloy layer on the preliminary metal layer, and etching the first preliminary alloy layer, the preliminary metal layer and the second preliminary alloy layer.

In an embodiment, each of the first preliminary alloy layer and the second preliminary alloy layer may include an alloy including titanium and zinc.

In an embodiment, the preliminary metal layer may include copper.

In an embodiment, the gate line may be etched in a way such that an angle between the side surface of the gate line and the substrate is in a range of about 80 degrees to about 90 degrees.

In an embodiment, the method may further include forming a data line on the sloped film and the inorganic film to cross the gate line.

In a display device according to embodiments of the disclosure, as the sloped film covers the side surface of the inorganic film overlapping the width direction of the gate line, a step difference of the gate line may be alleviated by the sloped film. Accordingly, by maximizing the cross-sectional area of the gate line and alleviating the step difference of the gate line, the resistance of the gate line may be reduced, and stringer defects due to the step difference may be effectively prevented in the manufacturing process.

In such embodiments, since the inorganic film covers the gate line and the sloped film is formed on the inorganic film, the gate line and the sloped film may not directly contact each other. Accordingly, by-products from a reaction between the gate line and the sloped film may not be formed, such that defects caused by the by-products may be effectively prevented.

In such embodiments, by forming the inorganic film and the sloped film on the gate line, even if the cross section of the gate line is formed in a substantially rectangular shape, a problem due to a step difference in the gate line may be effectively prevented in the subsequent process. Problems caused by the step differences, such as stringer defects, may be effectively prevented when the data lines are formed on the sloped film by reducing the step difference of the gate line. That is, through the inorganic film and the sloped film, resistance of the gate line may be reduced, and problems in the manufacturing process of the display device may be effectively prevented.

In such embodiments, since the sloped layer overlaps the side surface of the inorganic film and is not formed between the upper surface of the inorganic film and the gate line or is formed thinly, an additional process for forming a contact hole in the sloped layer may be omitted. That is, since an additional mask for forming the contact hole is not used, manufacturing cost and manufacturing time may be reduced during the manufacturing process of the display device. Accordingly, efficiency of the manufacturing process of the display device may be increased.

### BRIEF DESCRIPTION OF THE DRAWINGS

FIG. 1 is a plan view of a display device according to an embodiment of the disclosure.

FIG. 2 is a cross-sectional view taken along line I-I′ of FIG. 1.

FIG. 3 is an enlarged plan view of area A of FIG. 1.

FIG. 4 is a cross-sectional view taken along line II-II′ of FIG. 3.

FIG. 5 is an enlarged cross-sectional view of the gate line of FIG. 4.

FIG. 6 is a cross-sectional view showing another example of FIG. 5.

FIG. 7 is a cross-sectional view showing another example of FIG. 4.

FIG. 8 is a cross-sectional view showing another example of FIG. 2.

FIG. 9 is an enlarged cross-sectional view of area B of FIG. 8.

FIG. 10 is an enlarged cross-sectional view of the metal pattern of FIG. 9.

FIG. 11 is a cross-sectional view showing another example of FIG. 9.

FIGS. 12 to 23 are views showing a method of manufacturing a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, display devices in accordance with embodiments will be described in detail with reference to the accompanying drawings. The same reference numerals are used for the same components in the drawings, and any repetitive detailed descriptions of the same components will be omitted or simplified.

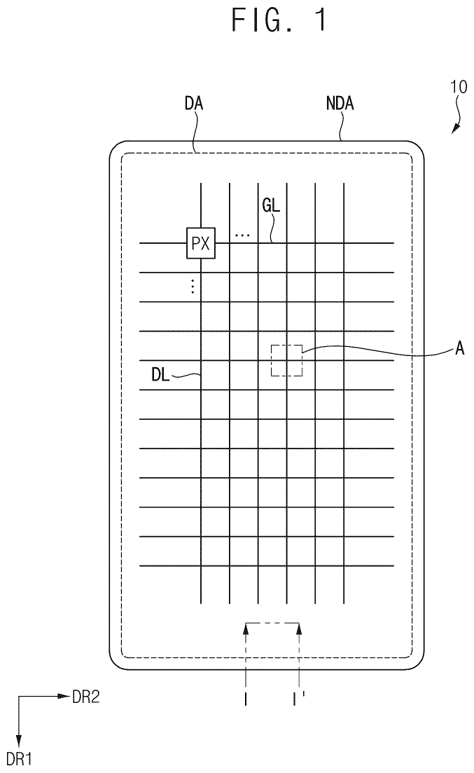

FIG. 1 is a plan view of a display device according to an embodiment of the disclosure.

Referring to FIG. 1, an embodiment of a display device 10 may include a display area DA and a non-display area NDA. The display area DA may be an area for displaying an image. A planar shape of the display area DA may be a rectangular shape or, as shown in FIG. 1, a rectangular shape with rounded corners. However, the planar shape of the display area DA is not limited thereto, and the display area DA may have various planar shapes such as a circular shape, an elliptical shape, and a polygonal shape.

The non-display area NDA may be disposed around the display area DA. The non-display area NDA may surround the display area DA. The non-display area NDA may be an area in which no image is displayed. In an embodiment, drivers for displaying an image of the display area DA may be disposed in the non-display area NDA.

Pixels PX may be arranged in a matrix form in the display area DA. Signal lines such as a gate line GL and a data line DL may be disposed in the display area DA. The signal lines, such as the gate line GL and the data line DL, may be connected to each of the pixels PX. Each of the pixels PX may receive a gate signal, a data signal, and the like through the signal line.

In an embodiment, for example, the gate lines GL may be arranged along a first direction DR1 and may extend in a second direction DR2 crossing the first direction DR1. The data lines DL may be arranged along the second direction DR2 and may extend in the first direction DR1.

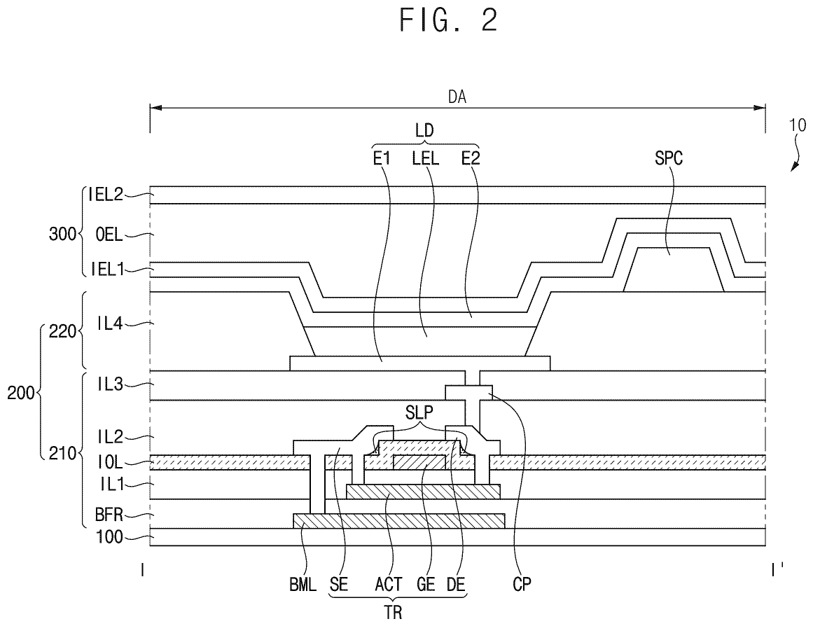

FIG. 2 is a cross-sectional view taken along line I-I′ of FIG. 1.

Referring to FIGS. 1 and 2, an embodiment of the display device 10 may include a substrate 100, a display element layer 200, and an encapsulation layer 300. The display element layer 200 may include a circuit element layer 210 and a light emitting element layer 220.

The circuit element layer 210 may be disposed on the substrate 100, and include a metal pattern BML, a buffer layer BFR, a transistor TR, a gate line, an inorganic film IOL, and an sloped film SLP, a connection electrode CP, a first insulation layer ILL a second insulation layer IL2, and a third insulation layer IL3. The transistor TR may include an active layer ACT, a gate electrode GE, a source electrode SE, and a drain electrode DE. The light emitting element layer 220 may be disposed on the circuit element layer 210 and may include a fourth insulation layer IL4, a spacer SPC, and a light emitting diode LD. The light emitting diode LD may include a first electrode E1, a light emitting layer LEL, and a second electrode E2.

The substrate 100 may support the display element layer 200. The substrate 100 may be a base substrate or a base member, and may include or be made of an insulating material such as a polymer resin. In an embodiment, for example, the substrate 100 may be a flexible substrate capable of being bent, folded, or rolled. In an alternative embodiment, for example, the substrate 100 may include a flexible material or a rigid material.

The metal pattern BML may be disposed on the substrate 100. The metal pattern BML may include a metal.

The buffer layer BFR may be disposed on the substrate 100. The buffer layer BFR may cover the metal pattern BML. The buffer layer BFR may effectively prevent diffusion of metal atoms or impurities from the substrate 100 into the active layer ACT.

The active layer ACT may be disposed on the substrate 100. The active layer ACT may overlap the metal pattern BML. The active layer ACT may be divided into a source region and a drain region, which are doped with impurities, and a channel region between the source region and the drain region.

The active layer ACT may include an oxide semiconductor. In an embodiment, for example, the oxide semiconductor may include a one-element metal oxide such as indium oxide (In), tin oxide (Sn), or zinc oxide (Zn), a binary metal oxide such as In—Zn-based oxide, Sn—Zn-based oxide, Al—Zn-based oxide, Zn—Mg-based oxide, Sn—Mg-based oxide, In—Mg-based oxide or In—Ga-based oxide, a ternary metal oxide such as In—Ga—Zn-based oxide, In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide or In—Lu—Zn-based oxide, or a quaternary metal oxide such as In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide or In—Hf—Al—Zn-based oxide. These materials may be used alone or in combination. In an embodiment, for example, the active layer ACT may include Indium-Gallium-Zinc Oxide (IGZO) among the In—Ga—Zn-based oxides. However, the disclosure is not limited thereto.

The first insulation layer IL1 may be disposed on the buffer layer BFR. The first insulation layer IL1 may cover the active layer ACT. However, the disclosure is not limited thereto, and alternatively, the first insulation layer IL1 may overlap the active layer ACT and have an island shape. In an embodiment, for example, the first insulation layer IL1 may include an inorganic material.

A gate layer including the gate line (e.g., a gate line GL of FIG. 4) and the gate electrode GE may be disposed on the first insulation layer IL1. In an embodiment, the gate electrode GE may overlap the channel region of the active layer ACT. However, the disclosure is not limited thereto, and alternatively, the gate electrode GE may be a portion of the gate line. Accordingly, a material of (or forming) the gate electrode GE and a thickness of the gate electrode GE may be the same as those of the gate line.

The inorganic film IOL may be disposed on the first insulation layer IL1. The inorganic film IOL may cover the gate line and the gate electrode GE. The inorganic film IOL may have a single-layer structure or a multi-layer structure. Also, the inorganic film IOL may include an inorganic material. In an embodiment, for example, the inorganic material constituting the inorganic film IOL may include silicon oxide, silicon nitride, or silicon oxynitride. These materials may be used alone or in combination.

The inorganic film IOL may cover the gate line and the gate electrode GE, and may have substantially the same (or constant) thickness along the profile of the gate line and the gate electrode GE. However, the disclosure is not limited thereto.

The sloped film SLP may be disposed on the inorganic film IOL. The sloped film SLP may cover a side surface IOLa of the inorganic film IOL.

The source electrode SE and the drain electrode DE may be disposed on the inorganic film IOL. The source electrode SE may contact the metal pattern BML through a first contact hole defined or formed in the buffer layer BFR, the first insulation layer IL′, and the inorganic film IOL. Also, the source electrode SE may contact the source region of the active layer ACT through a second contact hole defined or formed in the inorganic film IOL and the first insulation layer IL1. The drain electrode DE may contact the drain region of the active layer ACT through a third contact hole defined or formed in the second insulation layer IL2 and the inorganic film IOL. However, the disclosure is not limited thereto. In an alternative embodiment, the drain electrode DE may contact the metal pattern BML through a first contact hole formed in the buffer layer BFR, the first insulation layer IL′, and the inorganic film IOL and may contact the active layer ACT through a second contact hole defined or formed in the first insulation layer IL1 and the inorganic film IOL. In such an embodiment, the source electrode SE may contact the active layer ACT through a third contact hole defined or formed in the second insulation layer IL2.

The second insulation layer IL2 may be disposed on the inorganic film IOL. In addition, the second insulation layer IL2 may cover the source and drain electrodes SE and DE, and have a substantially flat upper surface without creating a step (or a stepped structure) around the source and drain electrodes SE and DE. In an embodiment, for example, the second insulation layer IL2 may include an organic material.

The connection electrode CP may be disposed on the second insulation layer IL2. The connection electrode CP may contact the source electrode SE or the drain electrode DE through a second contact hole defined or formed in the second insulation layer IL2.

The third insulation layer IL3 may be disposed on the second insulation layer IL2. In addition, the third insulation layer IL3 may cover the connection electrode CP and may have a substantially flat upper surface without creating a step around the connection electrode CP. In an embodiment, for example, the third insulation layer IL3 may include an organic material.

The first electrode E1 may be disposed on the third insulation layer IL3. The first electrode E1 may have reflective or light-transmitting properties. In an embodiment, for example, the first electrode E1 may include a metal.

The first electrode E1 may contact the connection electrode CP through a fourth contact hole defined or formed in the third insulation layer IL3, such that the first electrode E1 may be connected to the transistor TR.

The fourth insulation layer IL4 may be disposed on the third insulation layer IL3, and an opening exposing an upper surface of the first electrode E1 may be defined in the fourth insulation layer IL4. In an embodiment, for example, the fourth insulation layer IL4 may include an organic material or an inorganic material.

The spacer SPC may be disposed on the fourth insulation layer IL4. In an embodiment, for example, the spacer SPC may include an organic material or an inorganic material. The spacer SPC may maintain a gap between the encapsulation layer 300 and the display element layer 200.

In an embodiment, the spacer SPC may include a material different from that of the fourth insulation layer IL4. The spacer SPC may be formed after the fourth insulation layer IL4 is formed. However, embodiments according to the disclosure are not limited thereto, and alternatively, the spacer SPC may include a same material as the fourth insulation layer IL4. Also, the fourth insulation layer IL4 and the spacer SPC may be simultaneously formed using a halftone mask.

The light emitting layer LEL may be disposed on the first electrode E1. The light emitting layer LEL may be disposed in the opening formed in the fourth insulation layer IL4. In an embodiment, the light emitting layer LEL may have a multilayer structure including a hole injection layer, a hole transport layer, an organic light emitting layer, an electron transport layer, and an electron injection layer. The organic light emitting layer may include a light emitting material.

The second electrode E2 may cover the light emitting layer LEL and may be disposed on the fourth insulation layer IL4 and the spacer SPC. In an embodiment, the second electrode E2 may have a plate shape. In addition, the second electrode E2 may have light transmitting or reflecting properties. In an embodiment, for example, the second electrode E2 may include a metal.

The encapsulation layer 300 may effectively prevent moisture and oxygen from penetrating into the light emitting diode LD from the outside. In an embodiment, for example, the encapsulation layer 300 may include a first inorganic encapsulation layer IEL1, an organic encapsulation layer OEL, and a second inorganic encapsulation layer IEL2.

The first inorganic encapsulation layer IEL1 may be disposed on the second electrode E2 with substantially the same (or constant) thickness along the profile of the second electrode E2. The organic encapsulation layer OEL may be disposed on the first inorganic encapsulation layer IEL1, and may have a substantially flat upper surface without creating a step around the first inorganic encapsulation layer TELL The second inorganic encapsulation layer IEL2 may be disposed on the organic encapsulation layer OEL.

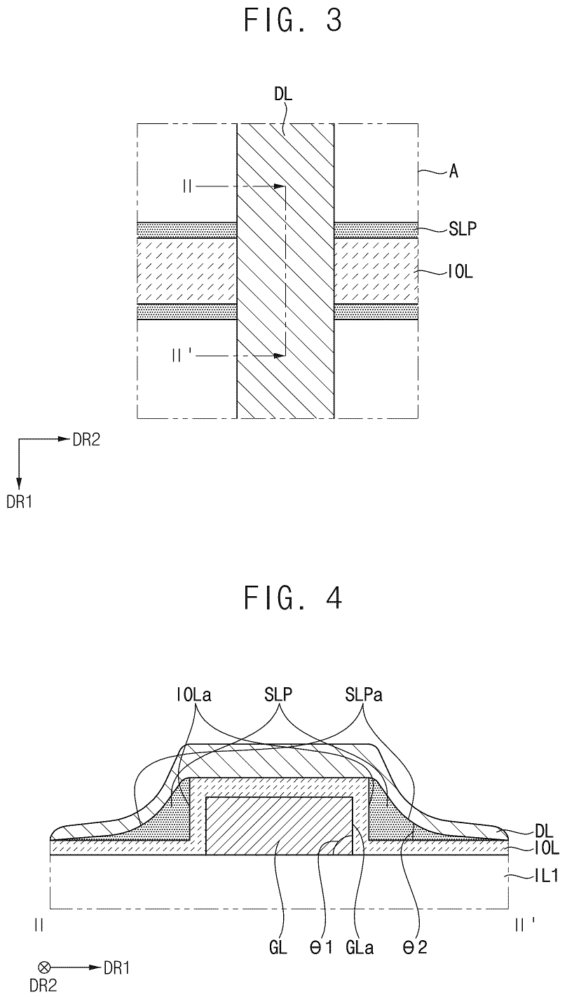

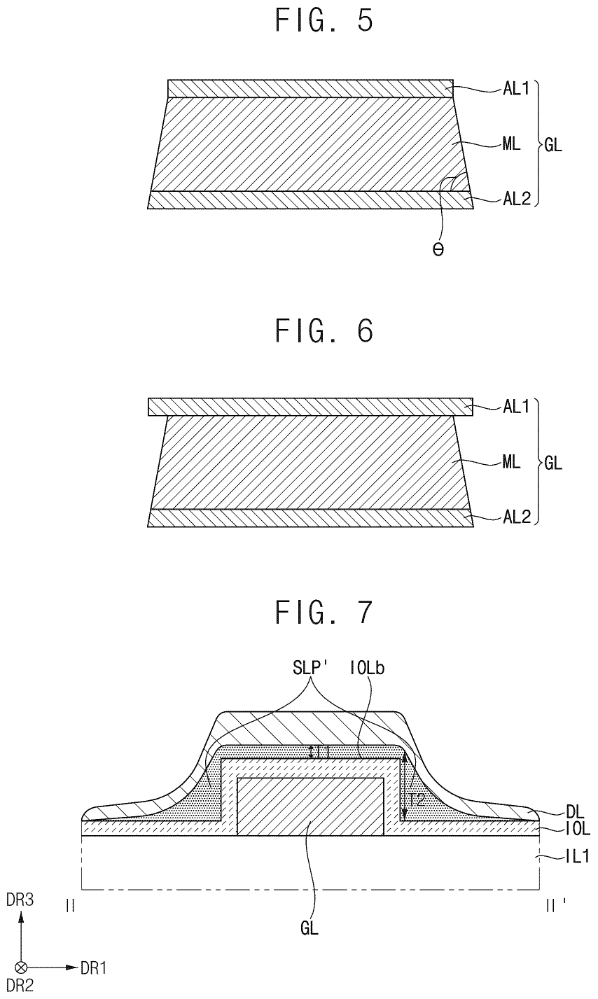

FIG. 3 is an enlarged plan view of area A of FIG. 1. FIG. 4 is a cross-sectional view taken along line II-II′ of FIG. 3. FIG. 5 is an enlarged cross-sectional view of the gate line of FIG. 4. Particularly, FIG. 4 may be a view in which the substrate 100 and the buffer layer BFR are omitted.

Referring to FIGS. 1 to 4, in an embodiment, the gate line GL and the data line DL may cross each other. The data line DL may be disposed on the inorganic film IOL and the sloped film SLP. The gate line GL may be disposed on the first insulation layer IL1. The gate line GL may include copper.

Referring further to FIG. 5, in an embodiment, the gate line GL may include a metal layer ML, a first alloy layer AL1, and a second alloy layer AL2. The first alloy layer AL1 may be disposed on the metal layer ML. The second alloy layer AL2 may be disposed under the metal layer ML. However, the disclosure is not limited thereto.

The metal layer ML may include copper. Each of the first alloy layer AL1 and the second alloy layer AL2 may include titanium. In addition, each of the first alloy layer AL1 and the second alloy layer AL2 may include zinc. That is, each of the first alloy layer AL1 and the second alloy layer AL2 may include an alloy including titanium and zinc.

A content of zinc included in each of the first alloy layer AL1 and the second alloy layer AL2 may be in a range of about 40 atomic percent (at %) to about 70 at %. If the content of zinc is less than about 40 at %, an etching rate of each of the first alloy layer AL1 and the second alloy layer AL2 may be lower than an etching rate of the metal layer ML. In this case, since a difference between the etching rate of each of the first alloy layer AL1 and the second alloy layer AL2 and the etching rate of the metal layer ML increases, a difference in a degree of etching may increase when the first alloy layer AL1, the metal layer ML, and the second alloy layer AL2 are etched. In this case, for example, the metal layer ML may be formed with a width smaller than each of the first alloy layer AL1 and the second alloy layer AL2. Therefore, it may be difficult to control the width of the gate line GL.

If the content of zinc is greater than about 70 at %, the etching rate of each of the first alloy layer AL1 and the second alloy layer AL2 may be greater than the etching rate of the metal layer ML. Similarly, in this case, since a difference in the etching rate between the first alloy layer AL1 and the second alloy layer AL2 and the etching rate of the metal layer ML increases, etching amount may be different from each other when etching the first alloy layer AL1, the metal layer ML, and the second alloy layer AL2. In this case, for example, each of the first alloy layer AL1 and the second alloy layer AL2 may be formed with a smaller width than the metal layer ML. Therefore, it may be difficult to control the width of the gate line GL.

Referring back to FIG. 4, an angle θ1 between the side surface GLa of the gate line GL and the substrate 100 may be in a range of about 80 degrees to about 90 degrees. That is, a cross section of the gate line GL may have a substantially rectangular shape. If the angle θ1 between the side surface GLa of the gate line GL and the substrate is smaller than about 80 degrees, a cross-sectional area of the gate line GL may be reduced, such that resistance of the gate line GL may increase. In an embodiment, for example, an angle θ between a side surface of the metal layer ML among the gate line GL and the substrate 100 may be in a range of about 80 degrees to about 90 degrees (see FIG. 5). However, the disclosure is not limited thereto.

In an embodiment, since the cross section of the gate line GL has a substantially rectangular shape, the cross sectional area of the gate line GL may be increased and resistance of the gate line GL may be reduced.

The inorganic film IOL may be disposed on the first insulation layer IL1 and may cover the gate line GL. The inorganic film IOL may be disposed with substantially the same (or constant) thickness along the profile of the gate line and the gate electrode GE. However, the disclosure is not limited thereto.

The sloped film SLP may cover the side surface IOLa of the inorganic film IOL. A side surface IOLa of the inorganic film IOL may be a surface of the inorganic film IOL overlapping the gate line GL in a width direction of the gate line GL. In an embodiment, for example, the gate line GL extends in the second direction, and the width direction of the gate line GL may be the first direction DR1. The gate line GL, the inorganic film IOL, and the sloped film SLP may overlap each other in the first direction DR1.

In an embodiment, the sloped film SLP may have a tapered shape. The sloped film SLP may have a tapered shape unlike the cross section (substantially rectangular shape) of the gate line GL. That is, the thickness T of the sloped film SLP may decrease as a distance between the gate line GL and the sloped film SLP increases in the first direction DR1, that is, as being away from the gate line GL in the first direction DR1.

In an embodiment, an angle θ2 between a side surface SLPa of the sloped film SLP and the substrate 100 may be less than the angle θ1 between the side surface GLa of the gate line GL and the substrate 100. That is, the side surface SLPa of the sloped film SLP may have a more gentle slope than the side surface GLa of the gate line GL.

The sloped film SLP may include an organic material and an inorganic material. In an embodiment, for example, the sloped film SLP may include SiO₂ and may further include siloxane or polyimide. That is, the sloped film SLP may be an organic/inorganic composite layer.

The data line DL may be disposed on the sloped film SLP. The data line DL may include a metal.

In an embodiment, the sloped film SLP covers the side surface of the inorganic film IOL overlapping the gate line GL in the first direction DR1, so that the step difference of the gate line GL may be alleviated due to the sloped film SLP. Therefore, by maximizing the cross-sectional area of the gate line GL and alleviating the step difference of the gate line GL, stringer defects due to the step difference in the manufacturing process may be effectively prevented by the sloped film SLP. Accordingly, reliability of the display device 10 may be improved.

In such an embodiment, the inorganic film IOL covers the gate line GL and the sloped film SLP is disposed or formed on the inorganic film IOL, such that the gate line GL and the sloped film SLP may not be directly contact each other. Accordingly, by-products from a reaction between the gate line GL and the sloped film SLP may not be formed. Therefore, defects caused by the by-products from the reaction between the gate line GL and the sloped film SLP may be effectively prevented by the inorganic film IOL.

FIG. 6 is a cross-sectional view showing another example of FIG. 5.

Referring to FIGS. 4 and 6, in an embodiment, the first alloy layer AL1 included in the gate line GL may protrude outward from the metal layer ML. That is, the gate line GL may have an undercut structure. In such an embodiment, the undercut structure of the gate line GL may be covered by the sloped layer SLP covering the side surface IOLa of the inorganic film IOL. That is, a step on the side surface of the gate line GL may also be alleviated by the gate line GL.

FIG. 7 is a cross-sectional view showing another example of FIG. 4.

Since a sloped film SLP′ in FIG. 7 is substantially the same as the sloped film SLP described with reference to FIG. 4 except for an overlapping range thereof with the inorganic film IOL and the gate line GL, any repetitive detailed descriptions thereof will be omitted.

Referring to FIG. 7, in an alternative embodiment, the sloped layer SLP′ may cover a side surface of the inorganic film IOL overlapping the gate line GL in the first direction DR1. The sloped film SLP′ may also overlap the inorganic film IOL and the gate line GL in a third direction DR3. The third direction DR3 may cross the first direction DR1 and the second direction DR2. That is, the sloped film SLP′ may further overlap an upper surface of the gate line GL and an upper surface IOLb of the inorganic film IOL.

A thickness T1 of a portion of the sloped film SLP overlapping the top surface of the gate line GL in the third direction DR3 may be less than a thickness T2 of a portion of the sloped film SLP adjacent to the side surface of the inorganic film IOL in the first direction DR1.

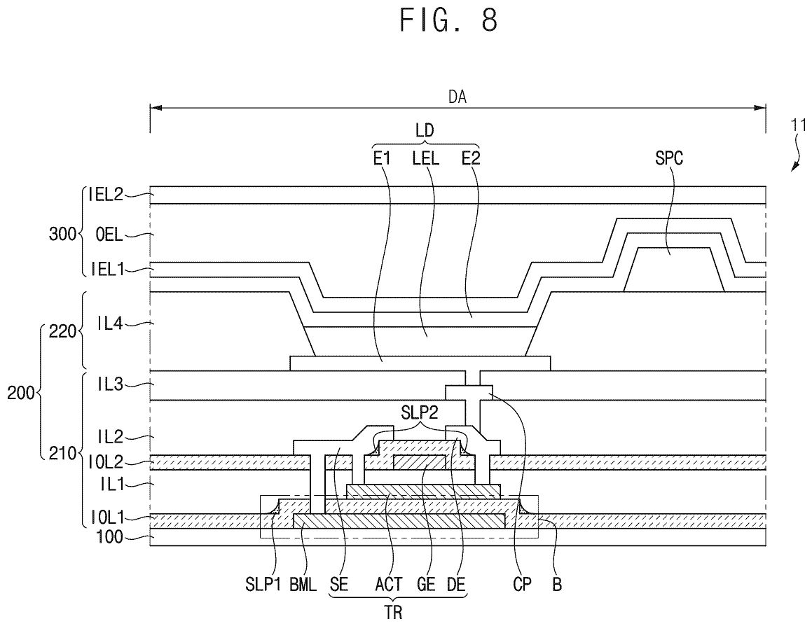

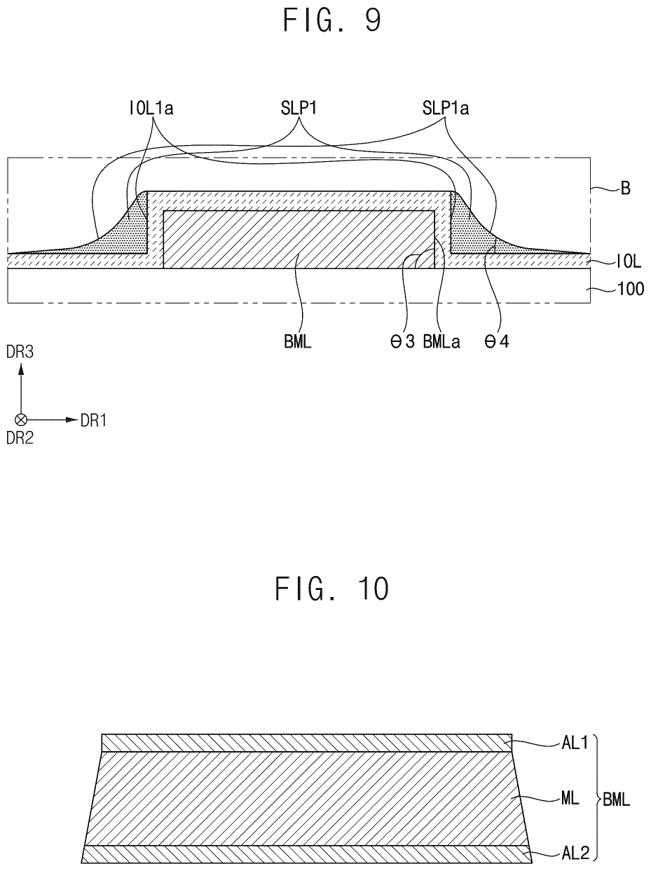

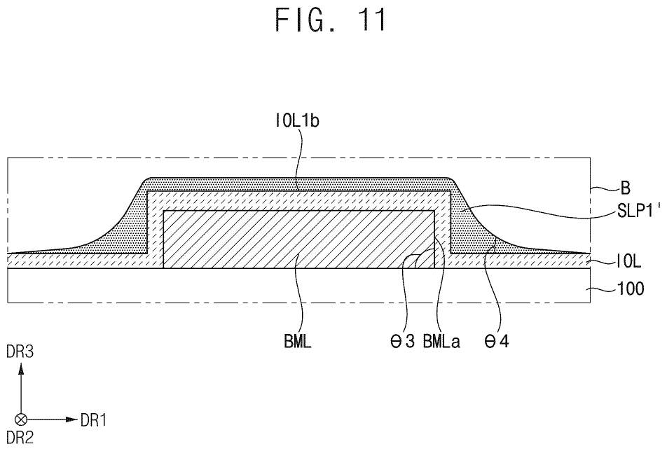

FIG. 8 is a cross-sectional view showing another example of FIG. 2. FIG. 9 is an enlarged cross-sectional view of area B of FIG. 8. FIG. 10 is an enlarged cross-sectional view of the metal pattern of FIG. 9.

Since a display device 11 shown in FIGS. 8 to 10 is substantially the same as the display device 10 described with reference to FIGS. 2 to 5 except that the display device 11 further includes a first inorganic film IOL1 and a first sloped layer SLP1, any repetitive detailed descriptions thereof will be omitted.

Referring to FIGS. 8 and 9, an embodiment of a display device 11 may further include a first inorganic film IOL1 and a first sloped film SLP1. The metal pattern BML may be disposed on the substrate 100.

An angle θ3 between a side surface BMLa of the metal pattern BML and the substrate 100 may be in a range of about 80 degrees to about 90 degrees. That is, the cross section of the metal pattern BML may have a substantially rectangular shape. In an embodiment, since the cross section of the metal pattern BML has a substantially rectangular shape, the cross sectional area of the metal pattern BML may increase and resistance of the metal pattern BML may decrease.

The first inorganic film IOL1 may be disposed on the substrate 100 and may cover the metal pattern BML. The first inorganic film IOL1 may be disposed with substantially the same (or constant) thickness along the profile of the metal pattern BML. However, the disclosure is not limited thereto. In an embodiment, the first inorganic film IOL1 may include an inorganic material.

The first sloped film SLP1 may be disposed on the first inorganic film IOL1 and may cover a side surface IOLla of the first inorganic film IOU. The side surface IOLla of the first inorganic film IOL1 may be a surface of the first inorganic film IOL1 overlapping the metal pattern BML in the width direction of the metal pattern BML. In an embodiment, for example, the width direction of the metal pattern BML may be the first direction DR1. However, the disclosure is not limited thereto. The metal pattern BML, the first inorganic film IOL1, and the first sloped film SLP1 may overlap each other in the first direction DR1.

In an embodiment, the first sloped film SLP1 may have a tapered shape. Unlike the cross section (substantially rectangular shape) of the metal pattern BML, the first sloped film SLP1 may have a tapered shape. That is, the thickness of the first sloped film SLP1 may decrease as the distance between the metal pattern BML and the first sloped film SLP1 in the first direction DR1 increases, that is, as being away from the metal pattern BML in the first direction DR1.

In an embodiment, an angle θ4 between the side surface SLP1a of the first sloped film SLP1 and the substrate 100 may be less than an angle θ3 between the side surface BMLa of the metal pattern BML and the substrate 100. That is, the side surface SLP1a of the first sloped film SLP1 may have a more gentle slope than the side surface BMLa of the metal pattern BML.

The first sloped film SLP1 may include an organic material and an inorganic material. In an embodiment, for example, the first sloped film SLP1 may include SiO₂ and may further include siloxane or polyimide.

The second inorganic film IOL2 may cover the gate line GL and the gate electrode GE. The second inorganic film IOL2 may include an inorganic material. The second sloped film SLP2 may cover the side surface of the second inorganic film IOL2 (e.g., the side surface IOLa of the inorganic film IOL of FIG. 4).

The second inorganic film IOL2 may be disposed to have substantially the same (or constant) thickness along the profile of the gate line GL and the gate electrode GE. However, the disclosure is not limited thereto.

Referring further to FIG. 10, the metal pattern BML may be disposed on the substrate 100. In an embodiment, for example, the metal pattern BML may include a metal layer ML, a first alloy layer AL1, and a second alloy layer AL2.

The metal layer ML may include copper. Each of the first alloy layer AL1 and the second alloy layer AL2 may include titanium. In addition, each of the first alloy layer AL1 and the second alloy layer AL2 may include zinc. That is, each of the first alloy layer AL1 and the second alloy layer AL2 may include an alloy including titanium and zinc.

A content of zinc included in each of the first alloy layer AL1 and the second alloy layer AL2 may be in a range of about 40 at % to about 70 at %. In such an embodiment where the content of zinc included in each of the first alloy layer AL1 and the second alloy layer AL2 is in the range of about 40 at % to about 70 at %, etching rates of the first and second alloy layers AL1 and AL2 may be similar to an etching rate of the metal layer ML. Accordingly, the width of the gate line GL may be easily controlled.

In an embodiment, since the first sloped film SLP1 covers the side surface of the first inorganic film IOL1 overlapping the metal pattern BML in the first direction DR1, the step difference of the metal pattern BML may be alleviated by the first sloped layer SLP1. Accordingly, stringer defects due to the step difference may be effectively prevented by the first sloped layer SLP1in the manufacturing process by alleviating the step difference of the metal pattern BML while maximizing the cross-sectional area of the metal pattern BML. Accordingly, reliability of the display device 11 may be improved.

In such an embodiment, since the first inorganic film IOL1 covers the metal pattern BML, and the first sloped film SLP1 is disposed or formed on the first inorganic film IOL1, the metal pattern BML and the first sloped film SLP1 may not directly contact each other. Accordingly, by-products from the reaction between the metal pattern BML and the first sloped film SLP1 may not be formed by the first inorganic film IOU. Therefore, defects caused by the by-products the reaction between the metal pattern BML and the first sloped film SLP1 may be effectively prevented.

FIG. 11 is a cross-sectional view showing another example of FIG. 9.

Since a first sloped film SLP1′ shown in FIG. 11 is substantially the same as the first sloped film SLP1 described with reference to FIG. 9 except for an overlapping range thereof with the first inorganic film IOL1 and the metal pattern BML, any repetitive detailed descriptions thereof will be omitted.

Referring to FIG. 11, a first sloped film SLP1 may cover a side surface of the first inorganic film IOL1 overlapping the metal pattern BML in the first direction DR1. The first sloped film SLP1 may also overlap the first inorganic film IOL1 and the metal pattern BML in the third direction DR3. That is, the first sloped film SLP1 may further overlap the upper surface of the metal pattern BML and the upper surface IOL1a of the first inorganic film IOL1.

A thickness of a portion of the first sloped film SLP1 overlapping the upper surface IOLla of the first inorganic film IOL1 in the third direction DR3 may be less than a thickness of a portion of the first sloped film SLP1 adjacent to the side surface of the first inorganic film IOL1 in the first direction DR1.

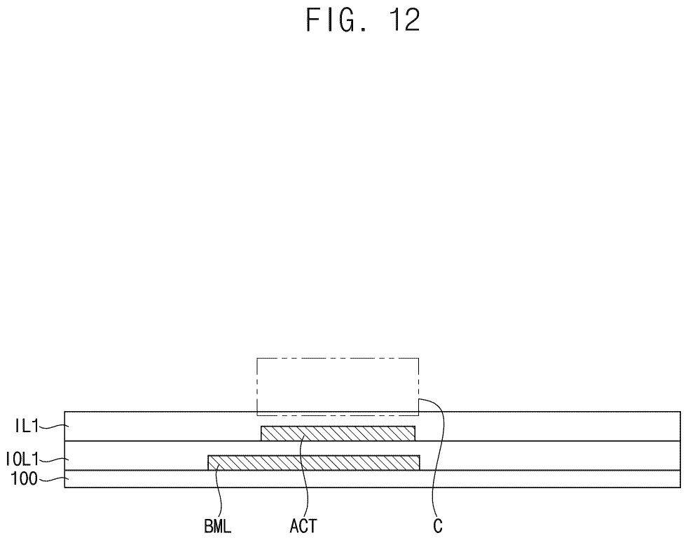

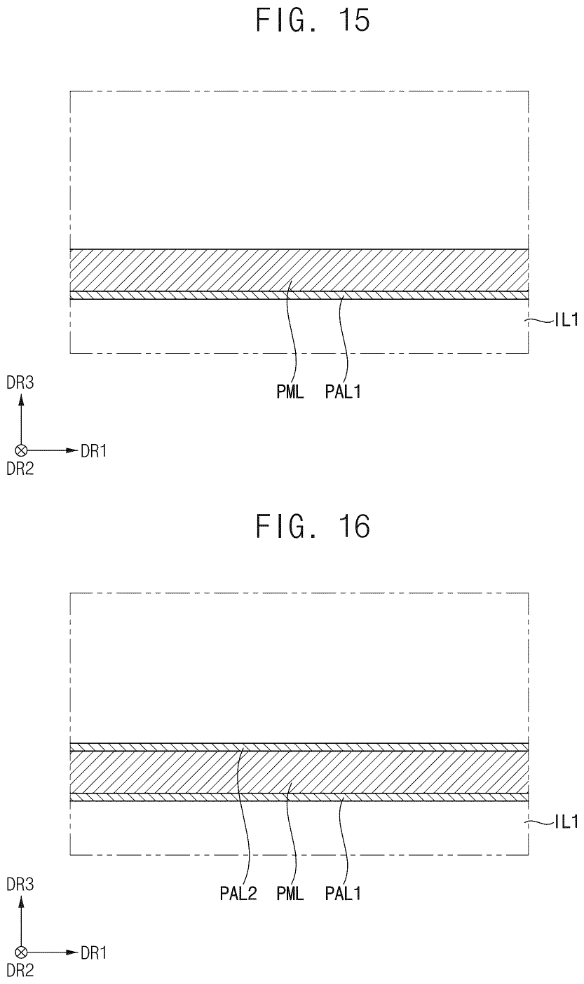

FIGS. 12 to 23 are views showing a method of manufacturing a display device according to an embodiment.

FIGS. 12 to 23 may show a method of manufacturing the display device 10 of FIGS. 1 to 5. Therefore, any repetitive detailed description of the same or like elements of the display device shown in FIGS. 12 to 23 as those described above will be omitted.

Referring to FIG. 12, a metal pattern BML may be formed (or provided) on the substrate 100. A buffer layer BFR may be formed on the substrate 100 to cover the metal pattern BML. An active layer ACT may be formed on the buffer layer BFR. A first insulation layer IL1 may be formed on the buffer layer BFR to cover the active layer ACT.

FIG. 13 is an enlarged cross-sectional view of area C of FIG. 12.

Referring to FIGS. 13 to 18, a gate line GL and a gate electrode may be formed on the first insulation layer IL1. Hereinafter, since the gate line GL and the gate electrode may be formed during a same process, processes for forming the gate line GL will be described in detail as a reference.

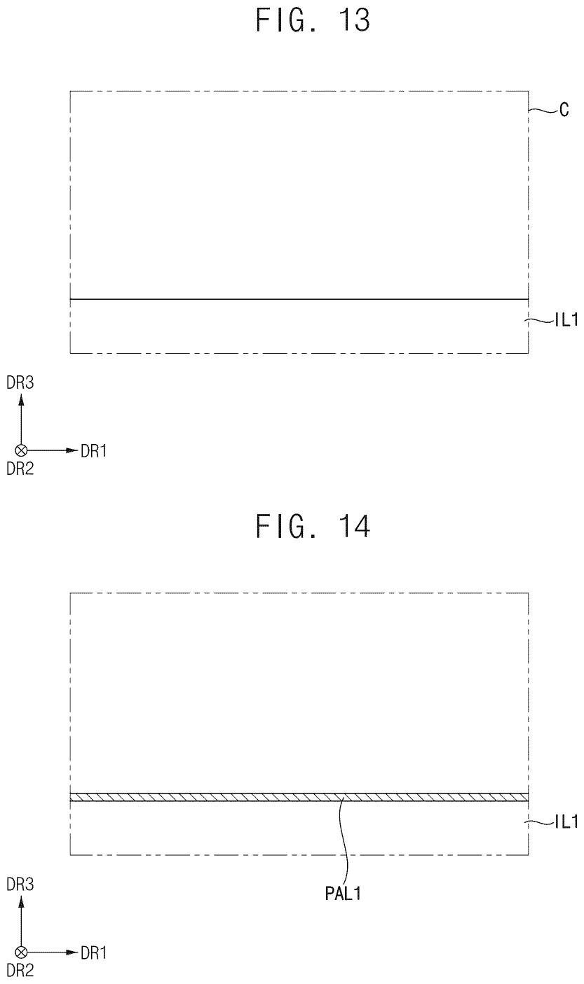

Referring to FIGS. 14 to 16, a first preliminary alloy layer PAL1 may be formed on the first insulation layer IL1. A preliminary metal layer PML may be formed on the first preliminary alloy layer PAL1. A second preliminary alloy layer PAL2 may be formed on the preliminary metal layer PML.

Each of the first preliminary alloy layer PAL1 and the second preliminary alloy layer PAL2 may be formed of an alloy including titanium and zinc. The preliminary metal layer PML may be formed of copper.

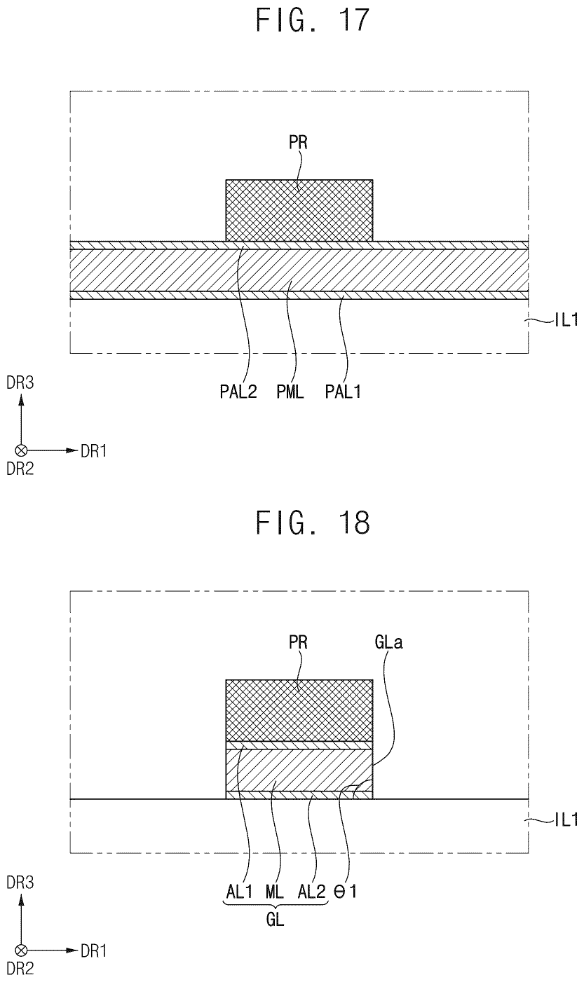

Further referring to FIGS. 17 and 18, a photoresist pattern PR may be formed on the second preliminary alloy layer PAL2. The first preliminary alloy layer PAL1, the preliminary metal layer PML, and the second preliminary alloy layer PAL2 may be etched through the photoresist pattern PR. In an embodiment, a second alloy layer AL2 may be formed on the first insulation layer IL1 by etching the first preliminary alloy layer PAL1, a metal layer ML may be formed on the second alloy layer AL2 by etching the preliminary metal layer PML, and a first alloy layer AL1 may be formed on the metal layer ML by etching the second preliminary alloy layer PAL2. Accordingly, the gate line GL including the first alloy layer AL1, the metal layer ML, and the second alloy layer AL2 and extending in the second direction DR2 may be formed.

When the first preliminary alloy layer PAL1, the preliminary metal layer PML, and the second preliminary alloy layer PAL2 are etched, etching rates of the first preliminary alloy layer PAL1, the preliminary metal layer PML, and the second preliminary alloy layer PAL2 may be different from each other. In an embodiment, a content of zinc included in each of the first preliminary alloy layer PAL1 and the second preliminary alloy layer PAL2 may be in a range of about 40 at % to about 70 at %. Accordingly, the etching rates of the first alloy layer AL1 and the second alloy layer AL2 may be similar to the etching rate of the metal layer ML. Accordingly, a width of the gate line GL may be easily controlled.

In an embodiment, when the first preliminary alloy layer PAL1, the preliminary metal layer PML, and the second preliminary alloy layer PAL2 are etched to form the gate line GL, the gate line GL may be etched in a way such that an angle θ1 between the side surface GLa of the gate line GL and the substrate 100 is in the range of about 80 degrees to about 90 degrees. That is, the cross section of the gate line GL may have a substantially rectangular shape. In such an embodiment where the angle θ1 between the side surface GLa of the gate line GL and the substrate 100 is in the range of about 80 degrees to about 90 degrees, the cross-sectional area of the gate line GL is maximized, thereby resistance of the gate line GL may be minimized.

After the gate line GL is formed, the photoresist pattern PR may be removed.

Further referring to FIG. 19, an inorganic film IOL may be formed on the gate line GL. The inorganic film IOL may be formed to cover the gate line GL. The inorganic film IOL may be formed of an inorganic material. The inorganic film IOL may cover the gate line GL and may have substantially the same (or constant) thickness along the profile of the gate line GL. However, the disclosure is not limited thereto.

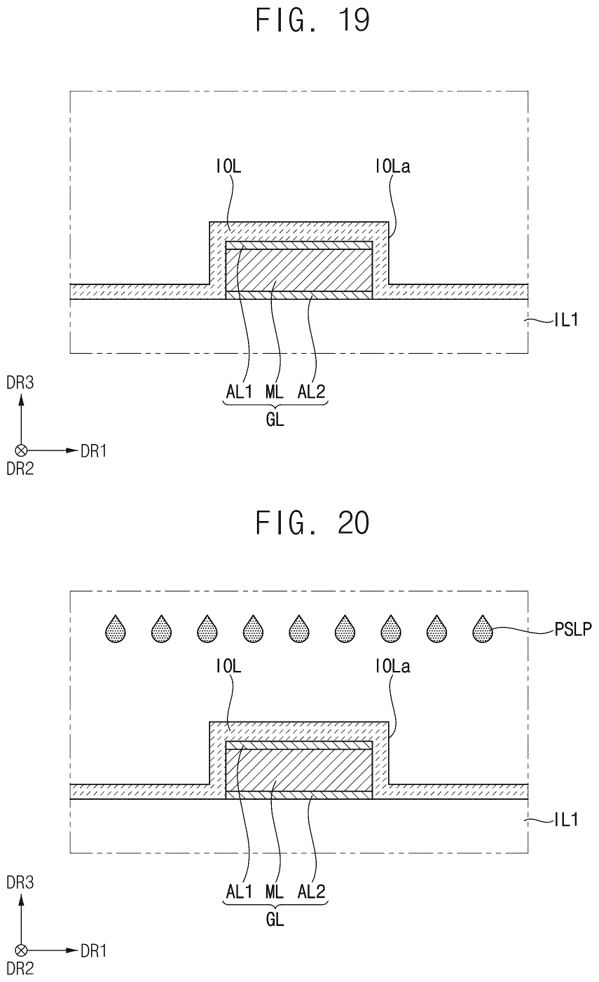

Further referring to FIGS. 20 to 22, an sloped film SLP may be formed on the inorganic film IOL.

Referring to FIG. 20, in detail, a preliminary sloped film PSLP may be entirely coated on the inorganic film IOL. The preliminary sloped film PSLP may be formed of an organic material or an inorganic material. In an embodiment, for example, the preliminary sloped film PSLP may include SiO₂ and may further include siloxane or polyimide. That is, the preliminary sloped film PSLP may be formed of an organic/inorganic composite layer.

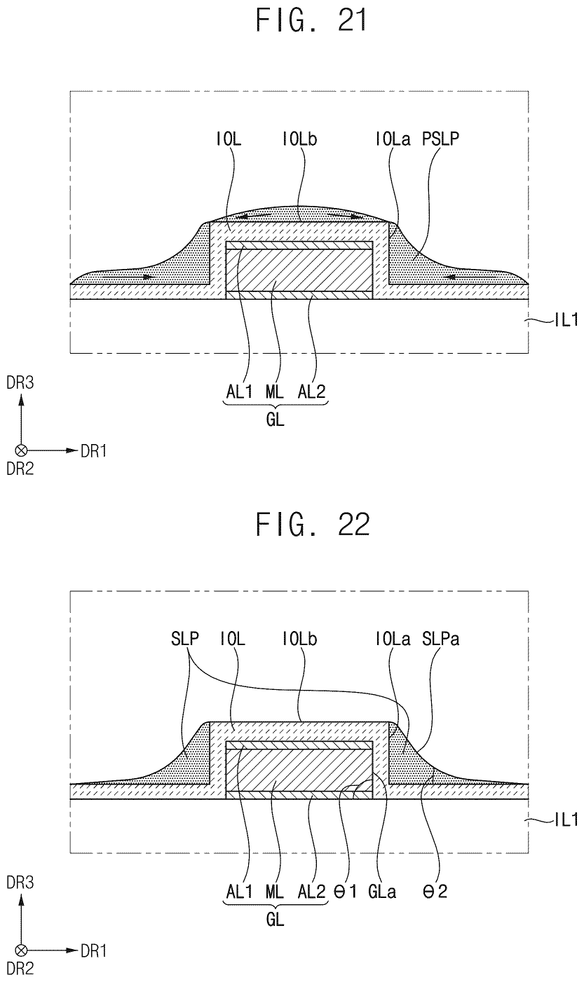

Referring to FIG. 21, the preliminary sloped film PSLP may have low viscosity and thus may flow down from the upper surface IOLb of the inorganic film IOL to the side surface IOLa of the inorganic film IOL.

Accordingly, the preliminary sloped film PSLP may hardly remain on the upper surface IOLb of the inorganic film IOL, and the preliminary sloped film PSLP may remain only on the side surface IOLa of the inorganic film IOL. In addition, the preliminary sloped film PSLP hardly remains even between adjacent gate lines GL, and may be attracted to the side surface IOLa of the inorganic film IOL. However, the disclosure is not limited thereto, and alternatively, the preliminary sloped film PSLP may remain on the upper surface IOLb of the inorganic film IOL or between adjacent gate lines GL.

Referring to FIG. 22, after the preliminary sloped film PSLP is entirely applied on the inorganic film IOL, the preliminary sloped film PSLP may be baked. By baking the preliminary sloped film PSLP, the sloped film SLP may be formed to cover the side surface IOLa of the inorganic film IOL.

An angle θ2 between the side surface SLPa of the sloped film SLP and the first insulation layer IL1 may be less than an angle θ1 between the side surface GLa of the gate line GL and the first insulation layer ILL

Accordingly, the sloped film SLP may cover the side surface IOLa of the inorganic film IOL and reduce a step difference caused by the gate line GL and the inorganic film IOL.

Since the inorganic film IOL is disposed between the sloped film SLP and the gate line GL, the sloped film SLP and the gate line GL may not directly contact each other. Accordingly, formation of by-products caused by a reaction between the sloped film SLP and the gate line GL may be effectively prevented.

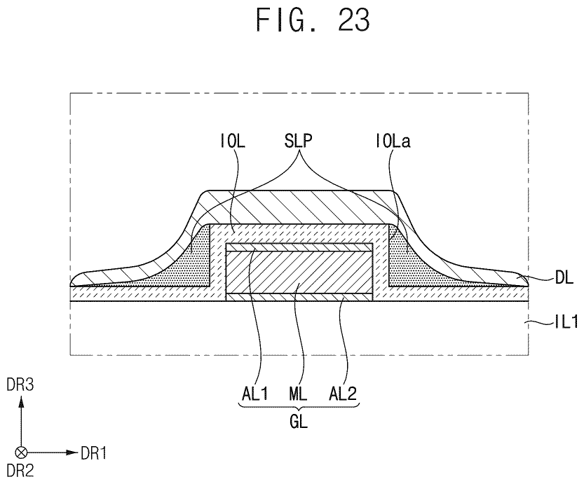

Further referring to FIG. 23, a data line DL may be formed on the sloped film SLP. The data line DL may extend in the first direction DR1 and may cross the gate line GL. The data line DL may be formed of a metal.

However, the disclosure is not limited thereto. In an embodiment, an inorganic film and an sloped film may be further formed on the metal pattern BML as well as the gate line GL (see FIGS. 8 to 10). Also, the metal pattern BML may include a first alloy layer, a second alloy layer, and a metal layer. The inorganic film may be formed on the substrate 100. The inorganic film may cover the metal pattern BML and may have substantially the same (or constant) thickness along the profile of the metal pattern BML.

In such an embodiment, the sloped film may be formed on the inorganic film and cover a side surface of the inorganic film. The sloped film may be formed on a side surface of the inorganic film to alleviate a step difference caused by the metal pattern BML and the inorganic film.

In an embodiment, since the inorganic film IOL and the sloped film SLP are formed on the gate line GL, even if the cross section of the gate line GL is formed in a substantially rectangular shape, a problem caused by the step difference of the gate line GL may be effectively prevented in the subsequent process. Since the sloped film SLP covers the step difference of the gate line GL, problems caused by the step difference, such as stringer defects, may be effectively prevented when the data line DL is formed on the sloped film SLP. That is, resistance of the gate line GL may be reduced through the inorganic film IOL and the sloped film SLP, and problems in the manufacturing process of the display device may be prevented.

In such an embodiment, since the sloped film SLP overlaps the side surface of the inorganic film IOL and is not formed or formed thin between the upper surface of the inorganic film IOL and the gate line GL, an additional process for forming a contact hole in the sloped film SLP may not be desired. That is, since an additional mask for forming the contact hole is not used, manufacturing cost and manufacturing time may be reduced during the manufacturing process of the display device. Accordingly, efficiency of the manufacturing process of the display device may be increased.

The display devices and the methods according to the embodiments may be applied to a display device included in a computer, a notebook, a mobile phone, a smartphone, a smart pad, a personal media player (PMP), a personal digital assistant (PDA), an MP3 player, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a gate line on the substrate;
an inorganic film on the substrate and covering the gate line; and
a sloped film on the inorganic film and covering a side surface of the inorganic film overlapping the gate line in a width direction of the gate line.

2. The display device of claim 1, wherein the sloped film has a tapered shape.

3. The display device of claim 1, wherein an angle between a side surface of the sloped film and the substrate is less than an angle between a side surface of the gate line and the substrate.

4. The display device of claim 1, wherein the gate line, the inorganic film, and the sloped film overlap each other in the width direction of the gate line.

5. The display device of claim 1, wherein a thickness of the sloped film decreases as being away from the gate line in the width direction of the gate line.

6. The display device of claim 1, wherein the sloped film includes an organic material and an inorganic material.

7. The display device of claim 6, wherein the sloped film includes SiO₂.

8. The display device of claim 7, wherein the sloped film further includes siloxane or polyimide.

9. The display device of claim 1, wherein an angle between a side surface of the gate line and the substrate is in a range of about 80 degrees to about 90 degrees.

10. The display device of claim 1, further comprising:
a data line on the sloped film.

11. The display device of claim 10, wherein the data line crosses the gate line.

12. The display device of claim 1, wherein the gate line includes copper.

13. The display device of claim 12, wherein the gate line includes:
a metal layer including copper;
a first alloy layer on the metal layer; and
a second alloy layer below the metal layer.

14. The display device of claim 13, wherein each of the first alloy layer and the second alloy layer includes titanium.

15. The display device of claim 14, wherein
each of the first alloy layer and the second alloy layer further includes zinc, and
a content of zinc included in each of the first alloy layer and the second alloy layer is in a range of about 40 at % to about 70 at %.

16. The display device of claim 1, wherein the sloped film further overlaps an upper surface of the gate line.

17. A display device comprising:
a substrate;
a metal pattern on the substrate;
a first inorganic film on the substrate and covering the metal pattern;
a first sloped film on the first inorganic film and covering a side surface of the first inorganic film overlapping the metal pattern in a width direction of the metal pattern; and
a gate line on the first sloped film and the first inorganic film.

18. The display device of claim 17, further comprising:
a second inorganic film on the first sloped film and the first inorganic film and covering the gate line; and
a second sloped film on the second inorganic film and covering a side surface of the second inorganic film overlapping the gate line in a width direction of the gate line.

19. The display device of claim 18, wherein each of the first sloped film and the second sloped film has a tapered shape.

20. The display device of claim 18, wherein
an angle between a side surface of the first sloped film and the substrate is less than an angle between a side surface of the metal pattern and the substrate, and
an angle between a side surface of the second sloped film and the substrate is less than an angle between a side surface of the gate line and the substrate.

21. The display device of claim 18, wherein each of the first sloped film and the second sloped film includes an organic material and an inorganic material.

22. A method of manufacturing a display device, the method comprising:
forming a gate line on a substrate;
forming an inorganic film on the substrate to cover the gate line; and
forming a sloped film on the inorganic film to cover a side surface of the inorganic film.

23. The method of claim 22, wherein the forming the sloped film includes
applying a preliminary sloped layer on the inorganic film; and
baking the preliminary sloped layer.

24. The method of claim 23, wherein the preliminary sloped layer includes an organic material and an inorganic material.

25. The method of claim 22, wherein the forming the gate line includes
forming a first preliminary alloy layer on the substrate;
forming a preliminary metal layer on the first preliminary alloy layer;
forming a second preliminary alloy layer on the preliminary metal layer; and
etching the first preliminary alloy layer, the preliminary metal layer, and the second preliminary alloy layer.

26. The method of claim 25, wherein each of the first preliminary alloy layer and the second preliminary alloy layer includes an alloy including titanium and zinc.

27. The method of claim 25, wherein the preliminary metal layer includes copper.

28. The method of claim 25, wherein the gate line is etched in a way such that an angle between a side surface of the gate line and the substrate is in a range of about 80 degrees to about 90 degrees.

29. The method of claim 22, further comprising:
forming a data line on the sloped film and the inorganic film to cross the gate line.
